(19) United States
(12) Patent Application Publication
(10) Pub. No.: US 2025/0048908 A1
(43) Pub. Date: Feb. 6, 2025

(54) DISPLAY PANEL AND DISPLAY MODULE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventor: Xin Mou, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/697,321

(22) PCT Filed: Aug. 14, 2023
(86) PCT No.: PCT/CN2023/112899

§ 371 Date: Mar. 29, 2024

(30) Foreign Application Priority Data
Sep. 29, 2022 (CN) 202211200771.6

(51) Int. Cl. H10K 59/80

(52) U.S. Cl. CPC H10K 59/8794; H10K 59/873

(57) ABSTRACT

The present disclosure relates to a display panel including a flexible substrate, where the flexible substrate includes a first side and a second side opposite to each other, an OLED device is arranged on the first side of the flexible substrate, and a heat dissipation functional film layer is directly attached to the flexible substrate at The second side, or, a thermal conductive film layer and a heat dissipation functional film layer are sequentially arranged on the flexible substrate at the second side in a direction away from the flexible substrate, and the thermal conductive film layer includes at least one sub-thermal conductive film layer arranged in a laminated manner. The present disclosure further relates to a display module.

### CROSS-REFERENCE TO RELATED APPLICATION

The present application claims priority to Chinese patent application No. 202211200771.6 filed in China on Sep. 29, 2022, which is incorporated herein by reference in its entirety.

### TECHNICAL FIELD

The present disclosure relates to the field of display product manufacturing technology, in particular to a display panel and a display module.

### BACKGROUND

An Organic light emitting diode (OLED) is known as a dream display due to such advantages as self-luminescence, high efficiency, bright color, light and thin, power-saving, rollable, and a wide temperature range. In recent years, the OLED has been widely used in the field of small and medium-sized displays, and gradually expands into the field of large-area displays and lighting.

A flexible and foldable panel allows for more flexible design, which may greatly improve the technical sense of an automobile display panel, and is a development trend of a vehicle-mounted panel in the future. However, Joule heating also occurs during the use of the OLED display panel, so that the temperature of the display panel increases (for example, when the ambient temperature is 26.3° C., which is room temperature, the temperature of an all-white display screen with a brightness of 600 nits without a heat dissipation structure is as high as 37.6° C. ˜43.1° C., and a temperature difference within the display panel is 5.5° C.) The increase in temperature accelerates the decay of brightness in the OLED display panel (for example, the decay speed of service life for the OLED display panel at 85° C. is significantly faster than that at room temperature, e.g., after 500 hours, the brightness at room temperature decays to 97.97% of an initial brightness, while at 85° C., the brightness decays to 72% of the initial brightness). The service life of an automobile often lasts for 10 years or even longer, so the requirement for the long-term thermal resistance of the panel is extremely high. How to improve the heat dissipation of the OLED panel is one of the technical challenges that need to be addressed by a person skilled in the art.

### SUMMARY

To address the above technical issue, the present disclosure provides a display panel and a display module, so as to mitigate the difficulty in heat dissipation of the display panel.

In order to achieve the foregoing objective, the present disclosure provides the following technical solutions: a display panel including a flexible substrate, where the flexible substrate includes a first side and a second side opposite to each other, an OLED device is arranged on the first side of the flexible substrate, and a heat dissipation functional film layer is directly attached to the flexible substrate at the second side, or, a thermal conductive film layer and a heat dissipation functional film layer are sequentially arranged on the flexible substrate at the second side in a direction away from the flexible substrate, and the thermal conductive film layer includes at least one sub-thermal conductive film layer arranged in a laminated manner.

Optionally, the heat dissipation functional film layer includes a high thermal conductivity adhesive made of one or more of acrylic resin, a silicon-based material, a thermal conductive silicone grease, or a liquid metal.

Optionally, the heat dissipation functional film layer further includes a metal layer on a side of the high thermal conductivity adhesive away from the flexible substrate.

Optionally, the heat dissipation functional film layer includes one or more layer films made of Al, Cu, a graphite sheet or Nano copper-carbon.

Optionally, the thermal conductive film layer includes one or two film layers of a bottom film layer, an embossed tape layer, or a buffer layer.

Optionally, the thermal conductive film layer includes the bottom film layer and/or the embossed tape layer arranged in a laminated manner, and the buffer layer is arranged on a side of the heat dissipation functional film layer away from the flexible substrate.

Optionally, a heat insulating layer is arranged on a side of the heat dissipation functional film layer away from the flexible substrate.

Optionally, the heat dissipation functional film layer includes a vapor chamber.

Optionally, a plurality of cooling columns is arranged on a side of the vapor chamber away from the flexible substrate.

Optionally, the display panel includes a flexible printed circuit board electrically connected via a chip on film, the flexible printed circuit board is bent to a side of the vapor chamber away from the flexible substrate, an orthographic projection of the flexible printed circuit board onto the vapor chamber is located in a first region, and the cooling columns are located in a second region on the vapor chamber adjacent to the first region.

Optionally, heights of the cooling columns in a direction perpendicular to the flexible substrate sequentially increase in a direction from the second region to the first region.

Optionally, a sectional area of at least one cooling column in a direction parallel to the flexible substrate gradually decreases in a direction away from the flexible substrate.

Optionally, a distribution density of the cooling columns sequentially increases in a direction from the second region to the first region.

Optionally, the flexible substrate is a curved surface structure that is at least bent in a first direction, and along the first direction, a distribution density of the cooling columns gradually increases from both ends of the vapor chamber to the middle of the vapor chamber.

Optionally, an area of orthographic projections of the cooling columns at a middle region of the vapor chamber onto the vapor chamber is a first area, an area of orthographic projections of the cooling columns at an edge region of the vapor chamber onto the vapor chamber is a second area, and the first area is greater than the second area.

Optionally, the flexible printed circuit board is connected to the vapor chamber by a connection element.

Optionally, at least one cooling column serves as the connection element.

An embodiment of the present disclosure further provides a display module including a cover plate, the above-mentioned display panel, and an optical film layer between the cover plate and the display panel, where
a temperature t1 at a first position on a light-exiting side of the OLED device meets the following formula:

$${t}_{1} = {t}_{∞} + {q}_{0} \frac{R 2}{R 1 + R 2} * \frac{1}{h}$$

a temperature t2 at a second position on a backlight side of the OLED device meets the following formula:

$${t}_{2} = {t}_{∞} + {q}_{0} \frac{R 1}{R 1 + R2} * \frac{1}{h}$$

R1 or R2 is obtained from the following formula:

$$R = \sum \frac{xi}{λ i} + \frac{1}{h}$$

q₀ is obtained from the following formula: q₀=p/s
where q₀ is a total heat flow density, p is a heat power of the display panel, s is a heat dissipation area of the display panel, R1 is a thermal resistance of the light-exiting side of the OLED device, R2 is a thermal resistance of the backlight side of said OLED device, x is a distance between the first position or the second position and the OLED device, λ is a thermal conductivity coefficient of each film layer between the first position or the second position and the OLED device, h is an air convective heat transfer coefficient, and t_{∞} is an ambient temperature.

The beneficial effect of the present disclosure is: removing one or more layers with poor thermal conductivity between the flexible substrate and the heat dissipation functional film layer, or even directly attaching the heat dissipation functional film layer to the flexible substrate at the backlight side, thereby effectively achieving the heat dissipation of the display panel.

### BRIEF DESCRIPTION OF THE DRAWINGS

FIG. 1 is a first schematic structural diagram of a display panel in the related art;

FIG. 2 is a first schematic structural diagram of a display panel according to an embodiment of the present disclosure;

FIG. 3 is a second schematic structural diagram of a display panel according to an embodiment of the present disclosure;

FIG. 4 is a third schematic structural diagram of a display panel according to an embodiment of the present disclosure;

FIG. 5 is a fourth schematic structural diagram of a display panel according to an embodiment of the present disclosure;

FIG. 6 is a fifth schematic structural diagram of a display panel according to an embodiment of the present disclosure;

FIG. 7 is a sixth schematic structural diagram of a display panel according to an embodiment of the present disclosure;

FIG. 8 is a schematic diagram of a heat dissipation simulation result;

FIG. 9 is a schematic diagram of a comparison between measured values and calculated values;

FIG. 10 is a seventh schematic structural diagram of a display panel according to an embodiment of the present disclosure;

FIG. 11 is an eighth schematic structural diagram of a display panel according to an embodiment of the present disclosure;

FIG. 12 is a first schematic diagram of a temperature distribution of a display panel;

FIG. 13 is a second schematic diagram of a temperature distribution of a display panel;

FIG. 14 is a ninth schematic structural diagram of a display panel according to an embodiment of the present disclosure;

FIG. 15 is a tenth schematic structural diagram of a display panel according to an embodiment of the present disclosure;

FIG. 16 is a eleventh schematic structural diagram of a display panel according to an embodiment of the present disclosure;

FIG. 17 is a second schematic structural diagram of a display panel in the related art;

FIG. 18 is a side view of the display panel in FIG. 17;

FIG. 19 is a twelfth schematic structural diagram of a display panel according to an embodiment of the present disclosure;

FIG. 20 is a side view of the display panel in FIG. 19;

FIG. 21 is a first schematic structural diagram of a flexible printed circuit board;

FIG. 22 is a second schematic structural diagram of a flexible printed circuit board;

FIG. 23 is a thirteenth schematic structural diagram of a display panel according to an embodiment of the present disclosure;

FIG. 24 is a fourteenth schematic structural diagram of a display panel according to an embodiment of the present disclosure;

FIG. 25 is a fifteenth schematic structural diagram of a display panel according to an embodiment of the present disclosure;

FIG. 26 is a sixteenth schematic structural diagram of a display panel according to an embodiment of the present disclosure;

FIG. 27 is a side view of the display panel in FIG. 26;

FIG. 28 is a seventeenth schematic structural diagram of a display panel according to an embodiment of the present disclosure;

FIG. 29 is a side view of the display panel in FIG. 28;

FIG. 30 is an eighteenth schematic structural diagram of a display panel according to an embodiment of the present disclosure.

### DETAILED DESCRIPTION

In order to make the objects, the technical solutions and the advantages of the present disclosure more apparent, the present disclosure will be described hereinafter in a clear and complete manner in conjunction with the drawings and embodiments. Apparently, the following embodiments merely relate to a part of, rather than all of, the embodiments of the present disclosure, and based on these embodiments, a person skilled in the art may, without any creative effort, obtain the other embodiments, which also fall within the scope of the present disclosure.

In the description of the present disclosure, it should be appreciated that, such words as “in the middle of”, “on/above”, “under/below”, “left”, “right”, “vertical”, “horizontal”, “inside” and “outside” may be used to indicate directions or positions as viewed in the drawings, and they are merely used to facilitate the description in the present disclosure, rather than to indicate or imply that a device or member must be arranged or operated at a specific position. In addition, such words as “first”, “second” and “third” may be merely used to differentiate different components rather than to indicate or imply any importance.

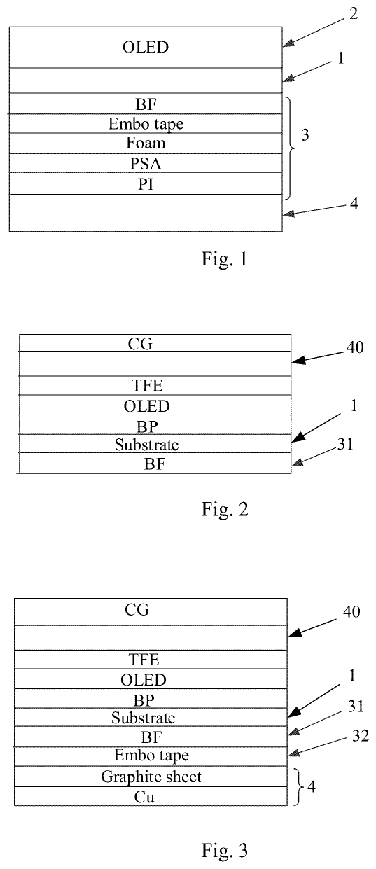

Referring to FIG. 2 to FIG. 30, embodiments of the present disclosure provide a display panel including a flexible substrate 1, the flexible substrate 1 includes a first side and a second side opposite to each other, an OLED device 2 is arranged on the first side of the flexible substrate, and a heat dissipation functional film layer 4 is directly attached to the flexible substrate at the second side, or, a thermal conductive film layer 3 and a heat dissipation functional film layer 4 are sequentially arranged on the flexible substrate at the second side in a direction away from the flexible substrate 1, and the thermal conductive film layer 3 includes at least one sub-thermal conductive film layer arranged in a laminated manner.

Referring to FIG. 1, in the related art, the effective heat dissipation functional film layer 4 is not in direct contact with the OLED display screen (that is, the effective heat dissipation functional film layer 4 is not in direct contact with the flexible substrate 1), and there are multiple plastic insulation layers therebetween (that is, the thermal conductive film layer 3, where thermal conductivities of various thermal conductive film layers are different, some of the film layers have relatively poor thermal conductivities and relatively strong insulation properties), such as PSA (pressure-sensitive adhesive) and PI (polyimide) film. The main purpose of the plastic insulation layers is to prevent the heat from other electronic elements such as an Integrated Circuit (IC), a Central Processing Unit (CPU), from spreading to the screen. Therefore, the combination of the heat dissipation film layer 4 and the thermal conductive film layer 3 actually functions as insulating the OLED screen, thereby to prevent the heat from other elements from spreading to the OLED screen 2, rather than dissipating the heat generated by the OLED screen 2.

In the embodiment of the present disclosure, the thermal conductive film layer 3 between the heat dissipation functional film layer 4 and the flexible substrate 1 is entirely removed, and the heat dissipation functional film layer 4 is directly attached to the flexible substrate 1 at the second side, or part of the thermal conductive film layer 3 is removed (the thermal conductive film layer 3 includes a plurality of sub-thermal conductive film layers, which herein refers to reducing the quantity of sub-thermal conductive film layers contained in the thermal conductive film layer 3). Only part of the sub-thermal conductive film layers are left between the flexible substrate 1 and the heat dissipation functional film layer 4. The thermal conductive film layer 3 and the heat dissipation functional film layer 4 are sequentially arranged on the flexible substrate at the second side, and the thermal conductive film layer 3 includes at least one sub-thermal conductive film layer arranged in a laminated manner. Thus, it is beneficial to reducing the temperature of the OLED device 2, slowing down the decay of brightness of the OLED display panel, and prolonging the service life.

In an exemplary embodiment, the heat dissipation functional film layer includes a high thermal conductivity adhesive made of one or more of acrylic resin, a silicon-based material, a thermal conductive silicone grease, or a liquid metal.

The heat dissipation of the OLED device is achieved through the high thermal conductivity adhesive with a high thermal conductivity, which accelerates the heat dissipation in a direction perpendicular to the flexible substrate and improves the overall heat dissipation effect of the display panel.

The thermal conductivity of the high thermal conductivity adhesive varies with different manufacturing materials. For example, the thermal conductivity of the liquid metal is 80 W/m·k.

In an exemplary embodiment, the heat dissipation functional film layer further includes a metal layer on a side of the high thermal conductivity adhesive away from the flexible substrate, referring to FIG. 7. Hence, it may further improve the overall heat dissipation effect of the display panel.

The function of the heat dissipation functional film layer 4 is to facilitate heat dissipation, and the heat dissipation functional film layer 4 may have various specific structural forms, including a single-layer or multi-layer heat dissipation film layer. In an exemplary embodiment, the heat dissipation functional film layer 4 includes one or more layer films made of Al, Cu, a graphite sheet or Nano copper-carbon.

In a display module including the display panel, an optical film layer 40 is further arranged on a light-exiting side of the display panel, and a cover plate CG is further arranged on a light-exiting side of the optical film layer 40. The optical film layer 40 may include, but not limited to, a polarizer and a touch layer. The OLED device 2 is a heat source, transmitting heat to the light-exiting side and the backlight side. The thickness and thermal conductivity of each film layer on the light-exiting side or the backlight side of the OLED device 2 are different, so the surface temperature of each film layer is different. The quantity of sub-thermal conductive film layers in the thermal conductive film layer and a specific structure of the sub-thermal conductive film layers may be determined based on a temperature of a light-exiting surface of the cover plate CG of the display module and a temperature of a bottom surface of the display module.

The heat transfer formula is used in the present disclosure, where a heat flow density q₀ is:
a total heat flow density:

$${q}_{0} = {q}_{1} + {q}_{2} = \frac{p}{s} ,$$

where p is a heat power of the OLED device, s is a heat dissipation area, q₁ is a heat flow density transferred to the light-exiting side, and q₂ is a heat flow density transferred to the backlight side.

According to the third type of boundary condition, a thermal resistance for steady-state heat transfer through a multi-layered wall may be expressed as:

$$R = {\sum }_{i = 1}^{n} \frac{{X}_{i}}{{λ}_{i}} + \frac{1}{h} ,$$

and it is able to obtain a thermal resistance R1 for transferring heat to the light-exiting side and a thermal resistance R2 for transferring heat to the backlight side.

Here, x is a thickness of a film layer on the light-exiting side or the backlight side of the OLED device, A is a thermal conductivity of the film layer on the light-exiting side or the backlight side of the OLED device, and h is an air convective heat transfer coefficient.

At heat equilibrium, the highest temperature point is located at the OLED device (specifically at the light-emitting layer of the OLED device), x=0, according to the following formulas:

$$t = {t}_{∞} + {q}_{1} ( \frac{a - x}{λ1} + \frac{1}{h} )$$

$$and$$

$$t = {t}_{∞} + {q}_{2} ( \frac{b - x}{λ 2} + \frac{1}{h} ) ,$$

the formula

$${q}_{1} ( \frac{a}{λ 1} + \frac{1}{h} ) = {q}_{2} ( \frac{b}{λ 2} + \frac{1}{h} )$$

is obtained, that is, q₁R1=q₂R2. Here, a is a thickness of a film layer at a first position on the light-exiting side of the OLED device (i.e., a distance between the OLED device and the first position), b is a thickness of a film layer at a second position on the backlight side of the OLED device (i.e., a distance between the OLED device and the second position). λ1 is a thermal conductivity of the film layer on the light-exiting side of the OLED device, λ2 is a thermal conductivity of the film layer on the backlight side of the OLED device, and t_{∞} is the ambient temperature.

According to the formulas

$${q}_{1} R 1 = {q}_{2} R 2$$

$$and$$

$${q}_{0} = {q}_{1} + {q}_{2} ,$$

$${q}_{1} = {q}_{0} \frac{R 2}{R 1 + R 2}$$

$$and$$

$${q}_{2} = {q}_{0} \frac{R 1}{R 1 + R 2}$$

may be obtained.

According to the above-mentioned formulas, when x=a, the temperature at the first position

$${t}_{1} = {t}_{∞} + {q}_{1} * \frac{1}{h}$$

when x=b, the temperature at the second position

$${t}_{2} = {t}_{∞} + {q}_{2} \frac{1}{h}$$

The following structural forms are selected to calculate the temperature of each film layer.

Structure 1: the thermal conductive film layer 3 includes one sub-thermal conductive film layer, which is the bottom film layer (BF) 31 (without the heat dissipation functional film layer), referring to FIG. 2.

Structure 2: the thermal conductive film layer 3 includes two sub-thermal conductive film layers, which include the bottom film layer (BF) 31 and the embossed tape layer (Embo tape) 32 arranged in a laminated manner. The heat dissipation functional film layer 4 includes the graphite sheet and copper metal layer arranged in a laminated manner, referring to FIG. 3.

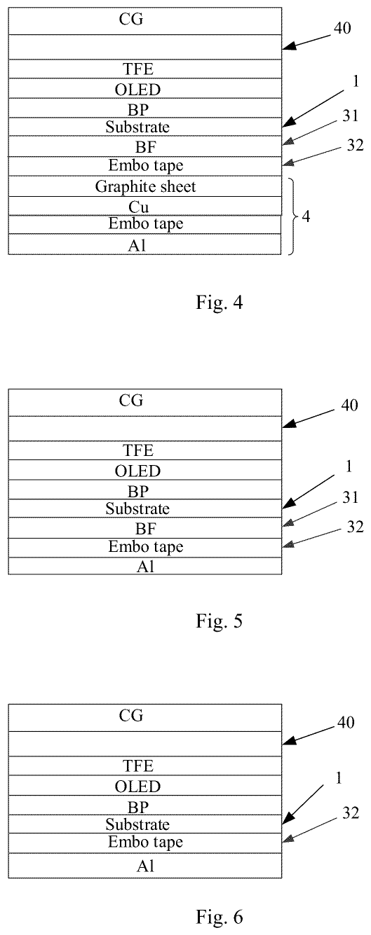

Structure 3: the thermal conductive film layer 3 includes two sub-thermal conductive film layers, which include the bottom film layer (BF) 31 and the embossed tape layer (Embo tape) 32 arranged in a laminated manner. The heat dissipation functional film layer 4 includes the graphite sheet and copper metal layer, and an embossed tape layer (Embo tape) and an Al plate are arranged in a laminated manner on the side of the heat dissipation functional film layer 4 away from the flexible substrate 1, referring to FIG. 4.

Structure 4: the thermal conductive film layer 3 includes two sub-thermal conductive film layers, which include the bottom film layer (BF) 31 and the embossed tape layer (Embo tape) 32 arranged in a laminated manner. The heat dissipation functional film layer 4 only includes the Al plate, referring to FIG. 5.

Structure 5: the thermal conductive film layer 3 includes one sub-thermal conductive film layer, which includes the embossed tape layer (Embo tape) 32. The heat dissipation functional film layer includes the Al plate, referring to FIG. 6.

Structure 6: no thermal conductive film layer is arranged between the flexible substrate 1 and the heat dissipation functional film layer 4, the flexible substrate 1 is in direct contact with the heat dissipation functional film layer 4, and the heat dissipation functional film layer 4 includes the high thermal conductivity adhesive and the Al plate arranged in a laminated manner, referring to FIG. 7.

The thickness and thermal conductivity of each film layer structure are shown in the following table 1:

| | | thermal |
|---|---|---|
| film material | thickness/μm | conductivity /W/m · k |
| bottom film(Polyethylene | 100 | 0.12 |
| Terephthalate PET material) | | |
| embossed tape layer | 25 | 0.12 |
| graphite | 15 | 129 |
| Cu | 100 | 401 |
| Al | 1000 | 237 |
| High thermal conductivity | 50 | 80 |
| adhesive (made of liquid metal) | | |

It should be noted that the high thermal conductivity adhesive in the above table is, but not limited to, made of liquid metal. In practical applications, the high thermal conductivity adhesives may also be made of acrylic resin and other materials.

The calculated temperature values are shown in the following table 2:

| | structure | structure | structure | structure | structure | structure |
|---|---|---|---|---|---|---|
| film layer | 1 | 2 | 3 | 4 | 5 | 6 |
| upper surface of CG | 29.18 | 29.23 | 29.33 | 29.23 | 29.08 | 28.97 |
| light-emitting layer of | 33.10 | 33.20 | 33.40 | 33.20 | 32.91 | 32.70 |
| OLED | | | | | | |
| lower surface of | 33.04 | 33.15 | 33.34 | 33.15 | 32.85 | 32.64 |
| flexible substrate | | | | | | |
| lower surface of | 32.93 | 33.03 | 33.23 | 33.03 | — | — |
| bottom film | | | | | | |
| lower surface of Cu | — | 32.33 | 32.54 | — | — | — |
| sheet | | | | | | |
| lower surface of Al | — | — | 32.23 | — | 32.48 | 32.59 |
| plate | | | | | | |

It should be noted that a back plane BP is arranged on a side of the flexible substrate 1. An OLED light-emitting layer is arranged on the back plane BP. An encapsulation layer TFE is arranged on the light-exiting side of the OLED light-emitting layer. An optical film layer 40 is arranged on a side of the encapsulation layer away from the OLED light-emitting layer. A cover plate CG is arranged on a side of the optical film layer 40 away from the OLED light-emitting layer. The above table does not show the specific temperature of the corresponding surface of each film layer.

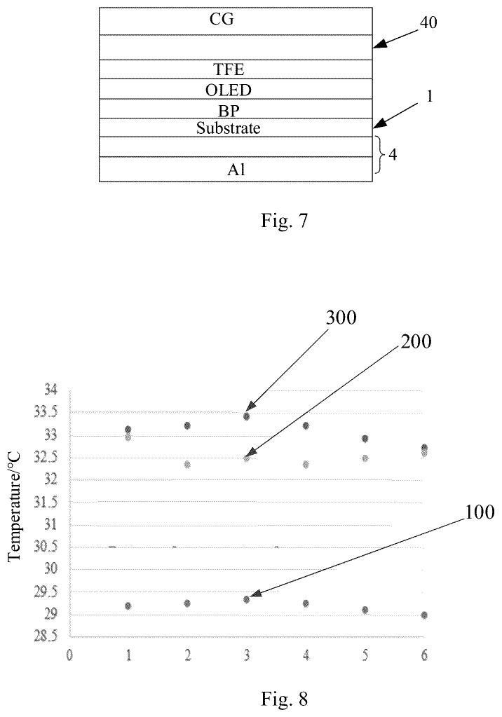

In FIG. 8, a dot denoted as 300 represents a temperature of the heat source (i.e., the temperature of the light-emitting layer of the OLED device). A dot denoted as 200 represents a temperature of a top surface (i.e., the temperature of the light-exiting surface of the cover plate) in each of the aforementioned six structures. A dot denoted as 100 represents a temperature of a bottom surface in each of the six structures.

From the above table and FIG. 8, it may be obtained that among the above structures, when structure 6 is adopted, and the temperature of the upper surface of the cover plate is the lowest.

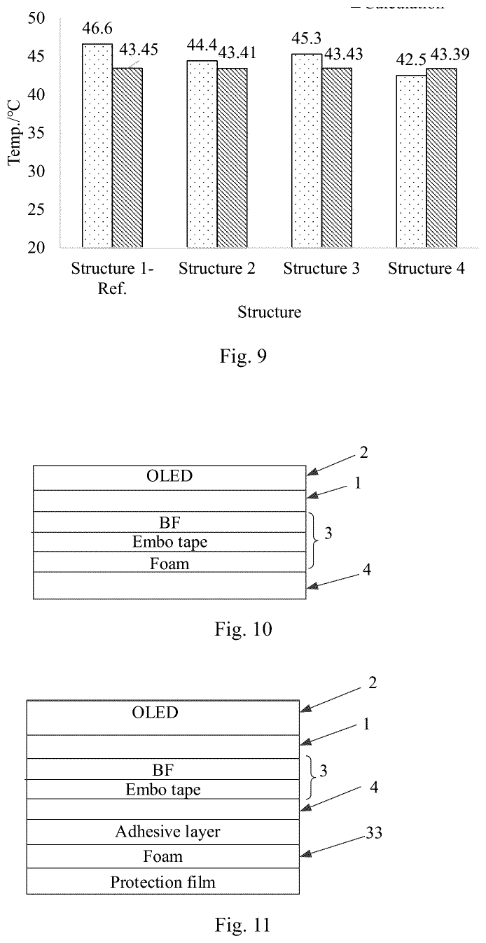

In the case of a white screen, a comparison between calculated values obtained through the above formulas and measured values is shown in FIG. 9 (FIG. 9 shows comparisons between measured values of the four structures from structure 1 to structure 4 and respective calculated values). In FIG. 9, a hatched pattern represents a calculated value, and a dotted pattern represents a measured value.

Referring to FIG. 9, it may be seen that for different structures, the temperature values (calculated values) calculated and obtained through the above formulas and the actual measured temperature values (measured values) have consistent trends. For example, the measured value in structure 1 is 46.6, the measured value in structure 2 is 44.4, and the temperature is on a decreasing trend. The calculated value in structure 1 is 43.45, the calculated value in structure 2 is 43.41, and the temperature is also on a decreasing trend. Therefore, the calculated values obtained through the above formulas provide guidance, and the quantity of sub-thermal conductive film layers may be increased or decreased based on the corresponding calculated values to meet the corresponding heat dissipation requirements.

When the display panel is used in a display screen, under a room temperature of 25° C., a heat power P of a vehicle-mounted display screen is 21.84 W, a laminated structure of the film layers of the display screen and the thermal conductivity and thickness of each film layer are as shown in the following table. The air convective heat transfer coefficient h is taken as 10 W/m²·k. The highest temperature t of the display screen (the temperature of the heat source, i.e., the temperature of the OLED device), the surface temperature t1 of the cover plate (CG), and the surface temperature t2 of the Al plate are calculated.

In the following table, a polarizer (pol), a first optically clear adhesive layer (COA2), a touch substrate (TSP), a second optically clear adhesive layer (COA1), and a cover plate (CG) are sequentially laminated one on another and on the light-exiting side of the display panel. A bottom film (BF), an embossed tape layer (EMBO), a foam adhesive layer (FOAM), a graphite sheet (GRAPHITE), a double-sided adhesive tape layer (DOUBLE TAPE), and an aluminum plate (Al) are sequentially laminated one on another and on the backlight side of the display panel.

| | | thermal | |
|---|---|---|---|
| film layer | size (mm) | conductivity (W/(m*K)) | thickness/mm |
| CG | 229*247*1.1 | 1 | 1.1 |
| OCA1 | 229*247*0.25 | 0.12 | 0.25 |
| TSP | 229*247*0.35 | 0.12 | 0.35 |
| OCA2 | 229*247*0.25 | 0.12 | 0.25 |
| C-POL | 229*247*0.216 | 0.12 | 0.216 |
| PANEL | 229*247*0.035 | 0.12 | 0.035 |
| BF | 229*247*0.1 | 0.12 | 0.1 |
| EMBO | 229*247*0.03 | 0.12 | 0.03 |
| FOAM | 229*247*0.16 | 0.18 | 0.16 |
| GRAPHITE | 229*247*0.017 | 15 | 0.017 |
| DOUBLE | 229*247*0.03 | 0.12 | 0.03 |
| TAPE | | | |
| AL | 229*247*1 | 237 | 1 |

The highest temperature

$$t = t ∞ + {q}_{0} \frac{R 1 R 2}{R 1 + R 2}$$

The upper surface temperature

$${t}_{1} = t ∞ + {q}_{0} \frac{R 2}{R 1 + R 2} * \frac{1}{h}$$

The lower surface temperature

$${t}_{2} = t ∞ + {q}_{0} \frac{R 1}{R 1 + R 2} * \frac{1}{h}$$

$$R = \sum \frac{xi}{λ i} + \frac{1}{h}$$

According to the foregoing formulas: R₁=0.1100, R₂=0.1022, q₀=386.1181, t=45.4573, t₁=43.6003, t₂=45.0115.

The following introduces several structural forms in the embodiment of the present disclosure.

In an exemplary embodiment, the thermal conductive film layer 3 includes one or two film layers of the bottom film layer (BF) 31, the embossed tape layer (Embo tape) 32, and the buffer layer 33 (for example, the foam adhesive layer Foam).

As compared with the traditional technology, in the thermal conductive film layer 3, not only the PSA (pressure-sensitive adhesive layer) and PI (polyimide film layer) are omitted, but also one of the bottom film layer (BF) 31, the embossed tape layer (Embo tape) 32 and the buffer layer 33 is removed. In this way, the heat generated by the OLED display panel during the operation may be more effectively transferred through the heat dissipation functional film layer 4, which is beneficial to reducing the temperature of the OLED display panel.

In an exemplary embodiment, the thermal conductive film layer 3 includes the bottom film layer (BF) 31 and/or the embossed tape layer (Embo tape) 32 arranged in a laminated manner. A buffer layer 33 (using the foam adhesive layer Foam, the foam adhesive layer Foam is bonded to one side of the heat dissipation functional film layer 4 through an adhesive layer) is arranged on the side of the heat dissipation functional film layer 4 away from the flexible substrate 1, referring to FIG. 11.

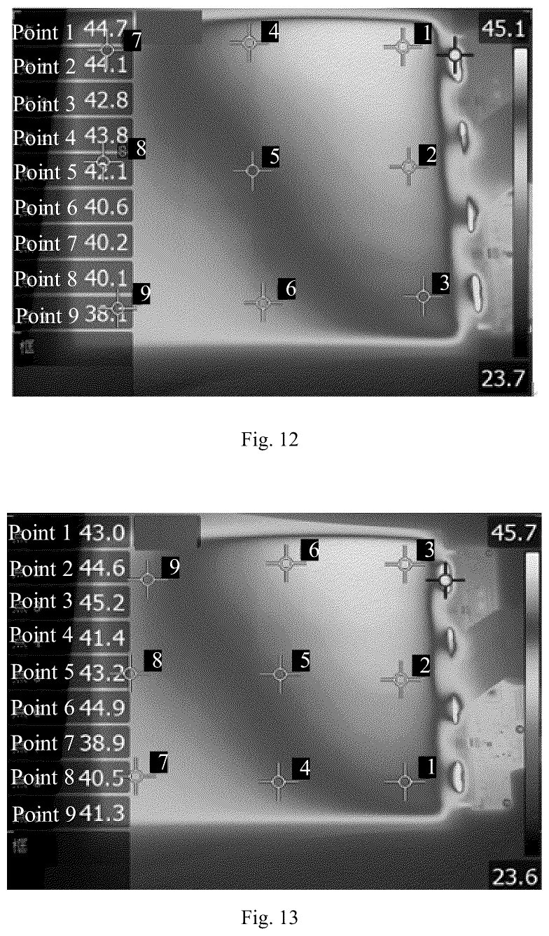

A reference structure is a structure shown in FIG. 1, where there are PSA (pressure-sensitive adhesive layer) and PI (polyimide film layer) above the heat dissipation functional film layer 4. In FIG. 11, the heat dissipation functional layer 4 is a metal layer (Cu) with a thickness of 80 μm and a graphite sheet with a thickness of 17 μm (not shown in FIG. 11). After the screen is energized at 800 nits for 1 hour, the screen brightness and surface temperature distribution corresponding to the structure in FIG. 1 are shown in FIG. 13, and the temperature distribution is 38.9-45.2° C. The screen brightness and surface temperature distribution corresponding to the structure in FIG. 11 are shown in FIG. 12, and the temperature distribution is 38.1° C.-44.7° C. The temperature is reduced by about 0.5° C.

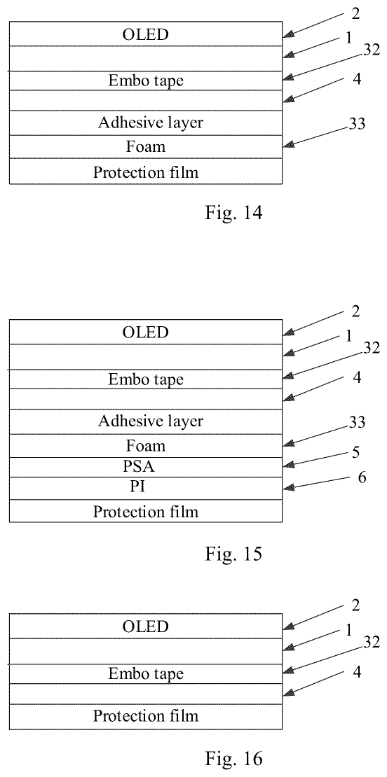

After the OLED light-emitting layer and the encapsulation layer are manufactured for the OLED screen, in order to avoid scratches on the OLED screen in the subsequent process, a temporary protective film, generally called a bottom film, is usually attached below the flexible substrate 1. This layer of film is usually made of such a plastic material as PI or PET, which has very poor thermal conductivity. In one implementation of this embodiment, the bottom film BF is removed on the basis of FIG. 11, referring to FIG. 14, the structure in FIG. 14 is more conducive to the heat dissipation of the OLED panel as compared to the structure in FIG. 11.

In an exemplary embodiment, a heat insulation layer is arranged on the side of the heat dissipation functional film layer 4 away from the flexible substrate 1.

In a case that there are electronic elements below the heat dissipation functional film layer 4, such as the Tcon FPC (Flexible Printed Circuit) required for driving the OLED screen, it is necessary to prevent the heat of the Tcon FPC from spreading to the OLED display screen. The heat insulation layer may be added on the side of the heat dissipation functional film layer 4 away from the flexible substrate 1. The heat insulation layer may be made of such insulating materials as PSA/PI, referring to FIG. 15, and the heat insulation layer includes a pressure-sensitive adhesive layer (PSA) 5 and a polyimide layer (PI) 6.

If the anti-mechanical vibration effect of the display screen meets the requirements, the foam adhesive layer that functions as buffering may be further omitted, referring to FIG. 16.

Referring to FIG. 20-FIG. 30, in an exemplary embodiment, the heat dissipation functional film layer 4 includes a vapor chamber.

The arrangement of the vapor chamber is beneficial to reducing the overall temperature of the OLED module (achieving uniformity while simultaneously achieving cooling through the vapor chamber (the neutralization of a high temperature part and a low temperature part, actually achieving cooling)) and improving the temperature uniformity within the surface.

It should be noted that heat pipes and vapor chambers (VC) are widely used in high-power or high-integration electronic products. The vapor chamber is a vacuum cavity with a capillary microstructure on an inner wall. The vapor chamber has the same basic principle and theoretical framework as the heat pipe. The difference is that a heat conduction manner is different. The heat conduction manner of the heat pipe is one-dimensional and linear conduction, while heat conduction manner of the vapor chamber is two-dimensional and surface conduction. Specifically, the liquid at the bottom of the vacuum cavity evaporates and diffuses into the vacuum cavity after absorbing the heat of the chip, transferring the heat to cooling fins, and condenses into a liquid back to the bottom. This process of evaporation and condensation, similar to that in a refrigerator and an air conditioner, rapidly cycles within the vacuum cavity, achieving fairly high heat dissipation efficiency.

The vapor chamber is a two-piece structure. A width of the vapor chamber may be customized arbitrarily, and theoretically is not limited. Due to a large area, the vapor chamber also has a relatively large maximum heat transfer capacity. Etching technology is used to etch protrusions on a copper plate, which serve as supports. A copper mesh, which serve as a capillary structure, is attached to the inside of another copper plate. Gaps between the copper pillars (that is, the protrusions) are vapor flow channels, and the copper mesh is a liquid return channel.

The vapor chamber is also a representative of phase-change heat conduction. The vapor chamber is also a heat dissipation unit filled with condensate, and is made of pure copper that is internally sealed and hollow (with an inner wall is not smooth but full of capillary structures). However, the form of the vapor chamber is not a flat “strip-like” shape of the heat pipe, but rather a wider flat “sheet-like shape”. The working principle of the vapor chamber shares similarities and differences with the heat pipe, but generally includes four steps: conduction→evaporation→convection →solidification. When an evaporation section of the vapor chamber is heated, the liquid in a suction wick inside the evaporation section evaporates, increasing pressure at this location. Under the effect of a pressure difference, vapor moves to a condensation section. After the vapor moves to the condensation section, the vapor is condensed into a liquid. The condensed liquid is transferred to the evaporation section through the suction wick by the action of capillary force, forming a cycle (a specific structure design of the vapor chamber may refer to the related art, which will not be elaborated herein).

In an exemplary embodiment, a plurality of cooling columns 20 is arranged on a side of the vapor chamber away from the flexible substrate.

It should be noted that in FIG. 20-FIG. 30, the flexible substrate and the OLED device are represented as a whole, that is, the display substrate denoted by 10 in FIG. 20-FIG. 30.

On the basis of the vapor chamber, the cooling columns 20 are added to further enlarge the heat dissipation area, which is beneficial to reducing the temperature of the OLED module, reducing the temperature difference within the surface of the OLED module, and mitigating the yellowing MURA (uneven brightness) phenomenon in a PCB back-folded region.

In an exemplary embodiment, the display panel includes a flexible printed circuit board 7 electrically connected via a chip on film. The flexible printed circuit board 7 is bent to the side of the vapor chamber away from the flexible substrate. An orthographic projection of the flexible printed circuit board 7 onto the vapor chamber is located in a first region, and the cooling columns 20 are located in a second region on the vapor chamber adjacent to the first region.

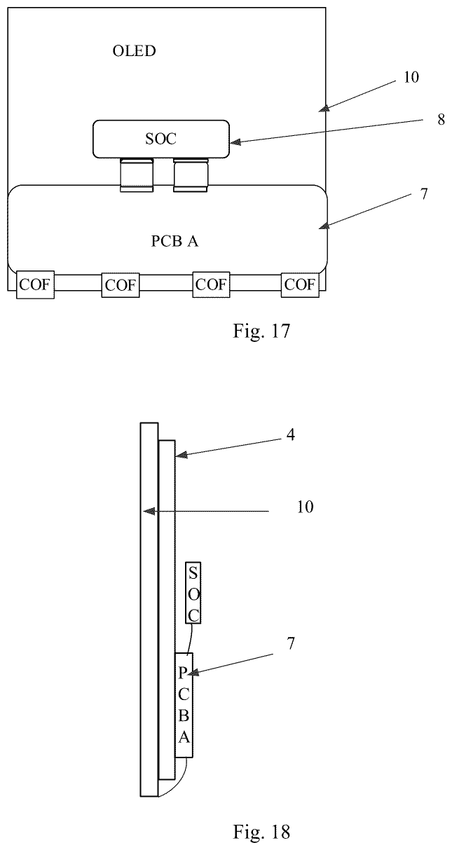

The conventional heat dissipation manner of the OLED module is to attach a heat dissipation film or heat dissipation aluminum plate onto a non-display surface of the screen, and a PCB (flexible printed circuit board) is back-folded to the aluminum plate, as shown in FIG. 17 and FIG. 18. Because there are high heat-generating devices on the PCB, the heat from the PCB 7 is transferred to the screen, causing the temperature at the lower end and the upper end of the screen to be inconsistent. The temperature at the upper end of the screen is low and the temperature at the lower end is high. Therefore, the brightness at the lower end decays faster than that at the upper end, causing an image at the lower end to turn yellow after a long time. In the embodiments of the present disclosure, the heat dissipation functional film layer 4 includes the vapor chamber, and the flexible printed circuit board 7 is bent to the side of the vapor chamber away from the flexible substrate, so as to improve the overall temperature uniformity of the display panel.

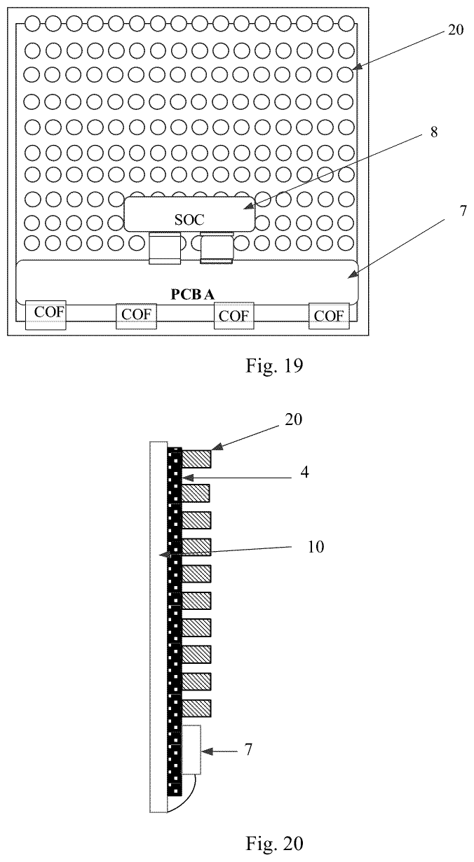

Comparing FIG. 17 and FIG. 19, as well as FIG. 18 and FIG. 20, it may be understood that in the embodiments of the present disclosure, a length of the flexible printed circuit board 7 (a length from the chip on film to the direction of the flexible printed circuit board) is reduced, thereby reducing an area of an orthographic projection of the flexible printed circuit board 7 onto the display substrate 10. As a result, a temperature difference caused by the flexible printed circuit board 7 is reduced.

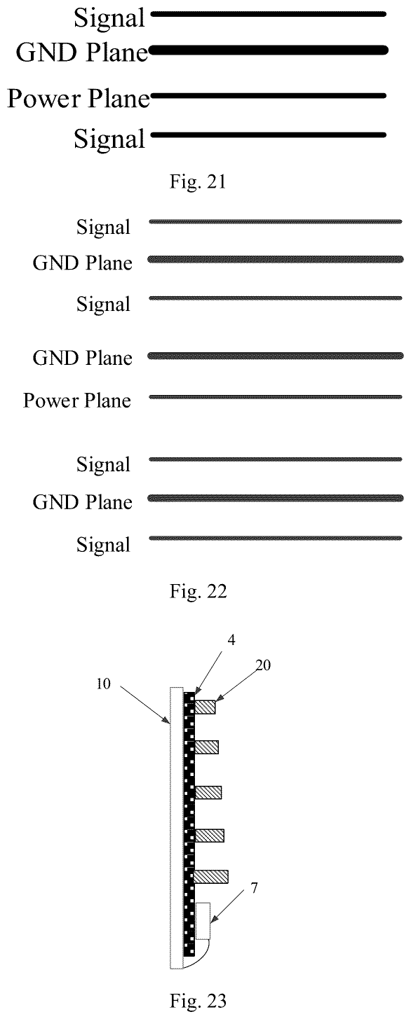

In an exemplary embodiment, in order to achieve the purpose of reducing the length of the flexible printed circuit board 7 (the length from the chip on film to the direction of the flexible printed circuit board), the flexible printed circuit board may adopt a multi-layer structure, and the quantity of laminated layers in the flexible printed circuit board may be even increased. Referring to FIG. 21 and FIG. 22, in FIG. 21, the flexible printed circuit board adopts a 4-layer structure (including two signal layers (signal wiring layers), and a GND plane layer (grounding layer) and a power plane layer (functional wiring layer) located between the two signal wiring layers), and in FIG. 22, the flexible printed circuit board adopts an 8-layer structure (including four signal layers (signal wiring layers), and a first signal wiring layer, a second signal wiring layer, a third signal wiring layer and a fourth signal wiring layer laminated one on another along a first direction, where a GND plane layer (grounding layer) is arranged between the first signal wiring layer and the second signal wiring layer, a GND plane layer (grounding layer) is arranged between the third signal wiring layer and the fourth signal wiring layer, a GND plane layer (grounding layer) and a power plane layer (functional wiring layer) are arranged between the second signal wiring layer and the third signal wiring layer). In a laminated structure of FIG. 22, relative to a laminated structure in FIG. 21, the reduction in the length of the flexible printed circuit board 7 (the length from the chip on film to the direction of the flexible printed circuit board) exceeds 50%, but is not limited to this.

It should be noted that in FIG. 7 and FIG. 8, the flexible printed circuit board includes a signal layer (signal wiring layer), a GND plane layer (grounding layer), and a power plane layer (functional wiring layer).

In an exemplary embodiment, heights of the cooling columns 20 in a direction perpendicular to the flexible substrate (that is, a direction perpendicular to the display substrate 10) sequentially increase in a direction from the second region to the first region. Referring to FIG. 23, due to the arrangement of the flexible printed circuit board 7, a temperature of a region close to the flexible printed circuit board is higher than a temperature of a region far from the flexible printed circuit board. When the heights of the cooling columns 20 in the direction perpendicular to the flexible substrate sequentially increase from the second region to the first region, it is able to reduce the temperature difference between the first region and the second region.

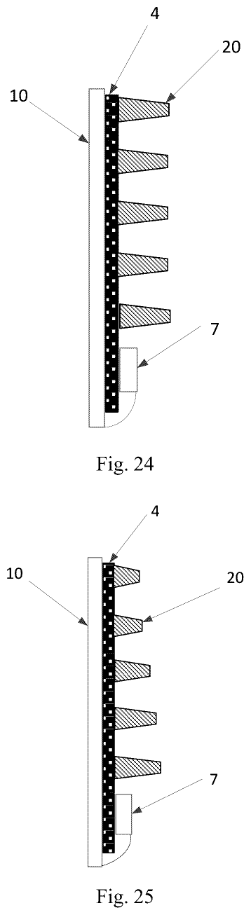

In an exemplary embodiment, a sectional area of at least one cooling column in a direction parallel to the flexible substrate gradually decreases in a direction away from the flexible substrate, referring to FIG. 24.

In an exemplary embodiment, the heights of the cooling columns 20 in the direction perpendicular to the flexible substrate (that is, the direction perpendicular to the display substrate 10) sequentially increase in the direction from the second region to the first region and a sectional area of at least one cooling column in the direction parallel to the flexible substrate gradually decreases in the direction away from the flexible substrate, referring to FIG. 25.

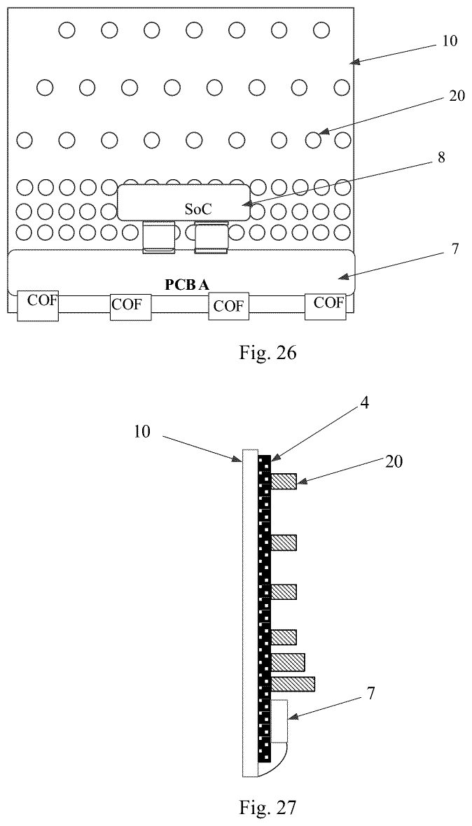

In an exemplary embodiment, a distribution density of the cooling columns sequentially increases in a direction from the second region to the first region, referring to FIG. 26 and FIG. 27.

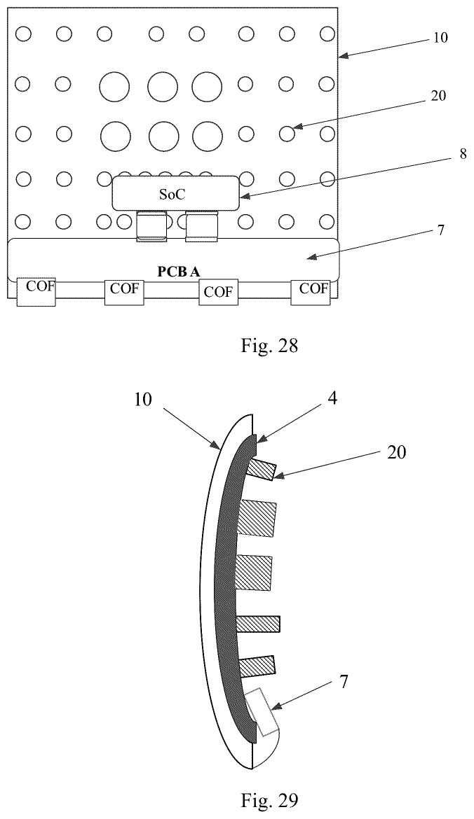

In an exemplary embodiment, the flexible substrate is a curved surface structure that is at least bent in a first direction (that is, the display substrate 10 is a curved surface structure that is at least bent in the first direction), and along the first direction, a distribution density of the cooling columns 20 gradually increases from both ends of the vapor chamber to the middle, referring to FIG. 28 and FIG. 29.

In an exemplary embodiment, an area of orthographic projections of the cooling columns 20 at a middle region of the vapor chamber onto the vapor chamber is a first area, an area of orthographic projections of the cooling columns 20 at an edge region of the vapor chamber onto the vapor chamber is a second area, and the first area is greater than the second area, referring to FIG. 28 and FIG. 29.

It should be noted that a size of the cooling column, an interval between the cooling columns, a height and a diameter of the cooling column are determined based on actual heat dissipation needs. The diameter of the cooling column is generally between 1 mm-50 mm, the interval between adjacent cooling columns is generally between 1 mm-30 mm, and the height of the cooling column is generally 0.5 mm-100 mm. The shape of the cooling column may be cylindrical (including a cylinder with different diameters at the top and bottom), elliptical, square, rectangular, conical, etc. The distribution of the cooling columns may be even or uneven. The height of the cooling columns may be consistent or inconsistent. The cooling columns may be upright or tilted.

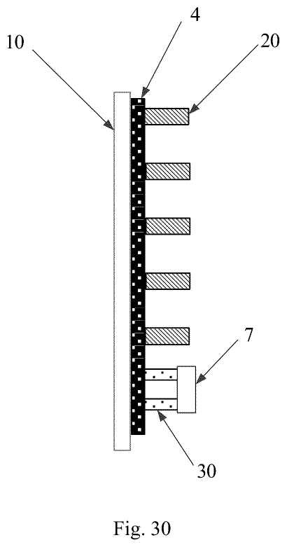

In an exemplary embodiment, the flexible printed circuit board 7 is connected to the vapor chamber by a connection element 30, referring to FIG. 30.

The connection element 30 may be a screw post, so as to prevent the flexible printed circuit board from being in direct contact with the vapor chamber.

In an exemplary embodiment, at least one cooling column serves as the connection element.

The embodiments of the present disclosure further provide a display module including a cover plate, the above-mentioned display panel, and an optical film layer between the cover plate and the display panel, where
a temperature at a first position t₁ on a light-exiting side of the OLED device meets the following formula:

$${t}_{1} = {t}_{∞} + {q}_{0} \frac{R 2}{R 1 + R 2} * \frac{1}{h}$$

a temperature at a second position t2 on a backlight side of the OLED device meets the following formula:

$${t}_{2} = {t}_{∞} + {q}_{0} \frac{R 1}{R 1 + R 2} * \frac{1}{h}$$

$$R = \sum \frac{xi}{λ i} + \frac{1}{h}$$

R1 or R2 is obtained from the following formula:
q₀ is obtained from the following formula: q₀=p/s
where q₀ is a total heat flow density, p is a heat power of the display panel, s is a heat dissipation area of the display panel, R1 is a thermal resistance of the light-exiting side of the OLED device, R2 is a thermal resistance of the backlight side of the OLED device, x is a distance between the first position or the second position and the OLED device, A is a thermal conductivity of each film layer between the first position or the second position and the OLED device, h is an air convective heat transfer coefficient, and t_{∞} is an ambient temperature.

The calculation results of the above formulas may be used as a reference to determine the quantity of sub-thermal conductive film layers included in the thermal conductive film layer and the use of specific materials.

It should be appreciated that the above embodiments are merely exemplary embodiments adopted to illustrate the principles of the present disclosure, but the present disclosure is not limited thereto. For those skilled in the art, various variations and improvements may be made without departing from the spirit and essence of the present disclosure, and these variations and improvements are also considered within the protection scope of the present disclosure.

1. A display panel comprising a flexible substrate, wherein the flexible substrate comprises a first side and a second side opposite to each other, an OLED device is arranged on the first side of the flexible substrate, and a heat dissipation functional film layer is directly attached to the flexible substrate at the second side, or, a thermal conductive film layer and a heat dissipation functional film layer are sequentially arranged on the flexible substrate at the second side in a direction away from the flexible substrate, and the thermal conductive film layer comprises at least one sub-thermal conductive film layer arranged in a laminated manner.

2. The display panel according to claim 1, wherein the heat dissipation functional film layer comprises a high thermal conductivity adhesive made of one or more of acrylic resin, a silicon-based material, a thermal conductive silicone grease, or a liquid metal.

3. The display panel according to claim 2, wherein the heat dissipation functional film layer further comprises a metal layer on a side of the high thermal conductivity adhesive away from the flexible substrate.

4. The display panel according to claim 1, wherein the heat dissipation functional film layer comprises one or more layer films made of Al, Cu, a graphite sheet or Nano copper-carbon.

5. The display panel according to claim 1, wherein the thermal conductive film layer comprises one or two film layers of a bottom film layer, an embossed tape layer, or a buffer layer.

6. The display panel according to claim 5, wherein the thermal conductive film layer comprises the bottom film layer and/or the embossed tape layer arranged in a laminated manner, and the buffer layer is arranged on a side of the heat dissipation functional film layer away from the flexible substrate.

7. The display panel according to claim 1, wherein a heat insulating layer is arranged on a side of the heat dissipation functional film layer away from the flexible substrate.

8. The display panel according to claim 1, wherein the heat dissipation functional film layer comprises a vapor chamber.

9. The display panel according to claim 8, wherein a plurality of cooling columns is arranged on a side of the vapor chamber away from the flexible substrate.

10. The display panel according to claim 9, wherein the display panel comprises a flexible printed circuit board electrically connected via a chip on film, the flexible printed circuit board is bent to the side of the vapor chamber away from the flexible substrate, an orthographic projection of the flexible printed circuit board onto the vapor chamber is located in a first region, and the cooling columns are located in a second region on the vapor chamber adjacent to the first region.

11. The display panel according to claim 10, wherein heights of the cooling columns in a direction perpendicular to the flexible substrate sequentially increase in a direction from the second region to the first region.

12. The display panel according to claim 9, wherein a sectional area of at least one cooling column in a direction parallel to the flexible substrate gradually decreases in a direction away from the flexible substrate.

13. The display panel according to claim 10, wherein a distribution density of the cooling columns sequentially increases in a direction from the second region to the first region.

14. The display panel according to claim 10, wherein the flexible substrate is a curved surface structure that is at least bent in a first direction, and along the first direction, a distribution density of the cooling columns gradually increases from both ends of the vapor chamber to the middle of the vapor chamber.

15. The display panel according to claim 14, wherein an area of orthographic projections of the cooling columns at a middle region of the vapor chamber onto the vapor chamber is a first area, an area of orthographic projections of the cooling columns at an edge region of the vapor chamber onto the vapor chamber is a second area, and the first area is greater than the second area.

16. The display panel according to claim 10, wherein the flexible printed circuit board is connected to the vapor chamber by a connection element.

17. The display panel according to claim 16, wherein at least one cooling column serves as the connection element.

18. A display module comprising a cover plate, the display panel according to claim 1, and an optical film layer between the cover plate and the display panel, wherein
a temperature at a first position t₁ on a light-exiting side of the OLED device meets the following formula:
$${t}_{1} = {t}_{∞} + {q}_{0} \frac{R 2}{R 1 + R 2} * \frac{1}{h}$$
a temperature at a second position t₂ on a backlight side of the OLED device meets the following formula:
$${t}_{2} = {t}_{∞} + {q}_{0} \frac{R 1}{R 1 + R 2} * \frac{1}{h}$$
$$R = \sum \frac{xi}{λ i} + \frac{1}{h}$$
R1 or R2 is obtained from the following formula:
q₀ is obtained from the following formula: q₀=p/s
wherein q₀ is a total heat flow density, p is a heat power of the display panel, s is a heat dissipation area of the display panel, R1 is a thermal resistance of the light-exiting side of the OLED device, R2 is a thermal resistance of the backlight side of the OLED device, x is a distance between the first position or the second position and the OLED device, A is a thermal conductivity of each film layer between the first position or the second position and the OLED device, h is an air convective heat transfer coefficient, and t_{∞} is an ambient temperature.

19. The display module according to claim 18, wherein the heat dissipation functional film layer comprises a vapor chamber.

20. The display module according to claim 19, wherein a plurality of cooling columns is arranged on a side of the vapor chamber away from the flexible substrate.
